(19) United States
(12) Patent Application Publication
(10) Pub. No.: US 2026/0255955 A1
(43) Pub. Date: Aug. 27, 2026

(54) DEEP TRENCH CAPACITOR (DTC) INTERCONNECT STRUCTURE FOR EMBEDDED POWER SUPPLY (EPS)

(71) Applicant: QUALCOMM Incorporated, San Diego, CA (US)

(72) Inventors: Aniket PATIL, San Diego, CA (US); Joan Rey Villarba BUOT, Escondido, CA (US); Zhijie WANG, San Diego, CA (US)

(21) Appl. No.: 19/065,903

(22) Filed: Feb. 27, 2025

(51) Int. Cl. H01L 23/522; H01L 23/528

(52) U.S. Cl. CPC H10W 20/496; H10W 20/42; H10W 20/427; H10W 20/43; H10W 20/435

(57) ABSTRACT

In an aspect, a substrate structure is disclosed comprising: a capacitor die having an array of capacitors, the capacitor die having a first die surface and a second die surface opposite the first die surface; a first set of through substrate vias (TSV) extending from a first set of electrodes of capacitors of the array of capacitors to a first set of contacts at the first die surface; a first set of metallization connecting the first set of contacts to a common first supply voltage; a second set of TSV extending from a second set of electrodes of the capacitors of the array of capacitors to a second set of contacts at the second die surface; and a second set of metallization connecting the second set of contacts to a common second supply voltage.

### FIELD OF DISCLOSURE

The present disclosure generally relates to electronic packaging, and more particularly, to a deep trench capacitor interconnect structure for an embedded power supply.

### BACKGROUND

Integrated circuit (IC) technology has achieved great strides in advancing computing power through miniaturization of electrical components. An IC may be implemented in the form of an IC chip that has a set of circuits integrated thereon. In some implementations, one or more IC chips can be physically carried and protected by an IC package, where various power and signal nodes of the one or more IC chips can be electrically coupled to respective conductive terminals of the IC package via electrical paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-electronic component devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth, and other communications), and the like.

In advanced electronic packaging, package miniaturization has become desirable due to the growing need for compact, high-performance devices in consumer electronics, automotive systems, and medical technologies. As electronic systems move toward the desired miniaturization goals, the space in an electronic package available to an EPS is greatly reduced. Although the space available for EPS is reduced, the power performance requirements of such EPS have increased in such aspects as voltage stability, current stability, power system noise, etc. To meet these demands, EPS often employ deep trench capacitors as decoupling/filtering components to stabilize the power system output.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an electronic device includes a substrate comprising a capacitor die having an array of capacitors, the capacitor die having a first die surface and a second die surface opposite the first die surface; a first set of through substrate vias (TSV) extending from a first set of electrodes of capacitors of the array of capacitors to a first set of contacts at the first die surface; a first set of metallization connecting the first set of contacts to a common first supply voltage; a second set of TSV extending from a second set of electrodes of the capacitors of the array of capacitors to a second set of contacts at the second die surface; and a second set of metallization connecting the second set of contacts to a common second supply voltage.

In an aspect, a substrate structure comprising: a capacitor die having an array of capacitors, the capacitor die having a first die surface and a second die surface opposite the first die surface; a first set of through substrate vias (TSV) extending from a first set of electrodes of capacitors of the array of capacitors to a first set of contacts at the first die surface; a first set of metallization connecting the first set of contacts to a common first supply voltage; a second set of TSV extending from a second set of electrodes of the capacitors of the array of capacitors to a second set of contacts at the second die surface; and a second set of metallization connecting the second set of contacts to a common second supply voltage.

In an aspect, a method of fabricating a substrate comprising: providing a capacitor die having an array of capacitors, the capacitor die having a first die surface and a second die surface opposite the first die surface, the capacitor die further having a first set of through substrate vias (TSV) extending from a first set of electrodes of capacitors of the array of capacitors to a first set of contacts at the first die surface, and a second set of TSV extending from a second set of electrodes of the capacitors of the array of capacitors to a second set of contacts at the second die surface; forming a first set of metallization connecting the first set of contacts to a common first supply voltage; and and forming a second set of metallization connecting the second set of contacts to a common second supply voltage.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, which are presented solely for illustration and not limitation of the disclosure.

FIG. 1 is a cross-sectional view of a deep trench capacitor (DTC) die, according to aspects of the disclosure.

FIG. 2 is a top plan view of the DTC die, according to aspects of the disclosure.

FIG. 3 is a cross-sectional view of a DTC die, according to aspects of the disclosure.

FIG. 4 is a top view of the DTC die showing the voltage bumps on both sides of the DTC die in the same view, according to aspects of the disclosure.

FIG. 5A through FIG. 5C show example layouts of voltage bumps at opposite sides of a DTC die, according to aspects of the disclosure.

FIG. 6 is a cross-sectional view of an example substrate structure, according to aspects of the disclosure.

FIG. 7A through FIG. 7F show example operations that may be used to fabricate a substrate structure, according to aspects of the disclosure.

FIG. 8 shows an example method of fabricating a substrate structure, according to aspects of the disclosure.

FIG. 9 illustrates a profile view of a package that includes a surface mount substrate, an integrated device, and an integrated passive device, according to aspects of the disclosure.

FIG. 10 illustrates an example method for providing or fabricating a package that includes an integrated device comprising a power splitter, according to aspects of the disclosure.

FIG. 11 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC).

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

As used herein, the term “contact” refers to any conductive element designed to establish an electrical connection, including: 1) pads, 2) pins, 3) bumps, or 4) any combination of such elements. As used herein, the term “metallization” refers to the patterned metallization layers, the metalized vias, and the contacts formed in a substrate that are configured to electrically connect the electrical components mounted on or in the substrate.

The terminology used herein is for the purpose of describing particular embodiments only and is not intended to be limiting As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Certain aspects of the disclosure are directed to providing compact substrate structures having deep trench capacitors (DTC) suitable for incorporation in an embedded power supply (EPS), according to aspects of the disclosure. As used herein, a DTC is a type of capacitor in which the capacitance is created using a deep trench structure in a substrate (e.g., a semiconductor substrate), with a first electrode (e.g., inner electrode) and a second electrode (e.g., outer electrode) separated by a thin dielectric layer. The vertical design allows for efficient charge storage and is widely used in advanced electronic systems.

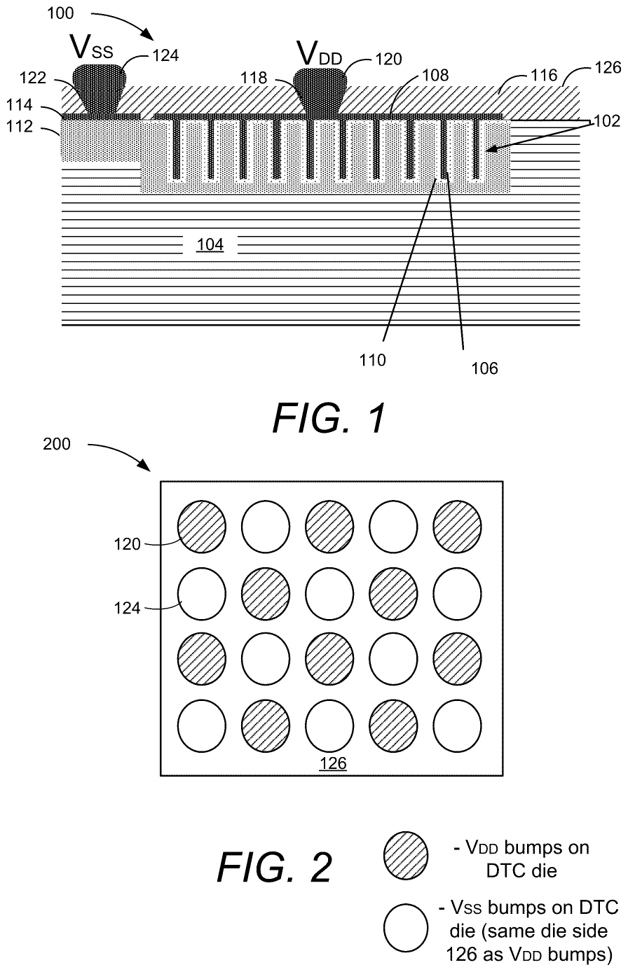

FIG. 1 is a cross-sectional view of a deep trench capacitor die 100, according to aspects of the disclosure. In this example, the DTC die 100 includes an array of DTCs. Each DTC is formed in trenches 102 of a semiconductor substrate 104. Each trench 102 includes a first electrode 106 formed, for example, by a metalized structure extending through a central portion of each trench 102. The first electrodes 106 of the DTC are connected to a conductive pad 108. Each of the first electrodes 106 is surrounded by a dielectric layer 110. In FIG. 1, the trenches 102 are surrounded by a second electrode 112 of the DTC formed, for example, by a highly-doped region of substrate 104. The second electrode 112 is electrically connected to a conductive pad 114.

The upper surface of the DTC die 100 includes a dielectric layer 116 overlying the conductive pads 108 and 114. A via structure 118 extends through the dielectric layer 116 and connects the conductive pad 108 to a voltage bump 120. A further via structure 122 extends through the dielectric layer 116 and connects the conductive pad 114 to a further voltage bump 124.

DTCs serving as bypassing/filter capacitors for an EPS are often connected to the voltage source supply (Vss) and voltage drain supply (V_{DD}) of the embedded power supply. Typically, Vss is connected to the second electrode 112, and V_{DD} is connected to the first electrode 106. In conventional scenarios, the connections to both voltages are made at the same side of the DTC die 100 (e.g., side 126), as shown in FIG. 1.

FIG. 2 is a top plan view 200 of the DTC die 100, according to aspects of the disclosure. In this example, the DTC die 100 includes an array of DTCs (e.g., 10 DTCs). Here, the top plan view 200 shows the voltage bumps connected to the electrodes of the DTCs in the array. As shown, all of the voltage bumps for all of the DTCs of the array are disposed at the same side 126 of the DTC die 100 in this conventional die architecture. There are two voltage bumps associated with each DTC of the DTC array (e.g., 20 voltage bumps in this example). Each voltage bump 120 is provided for connecting V_{DD} to the first electrode of the DTC, while each voltage bump 124 is provided for connecting the second electrode of the DTC to Vss.

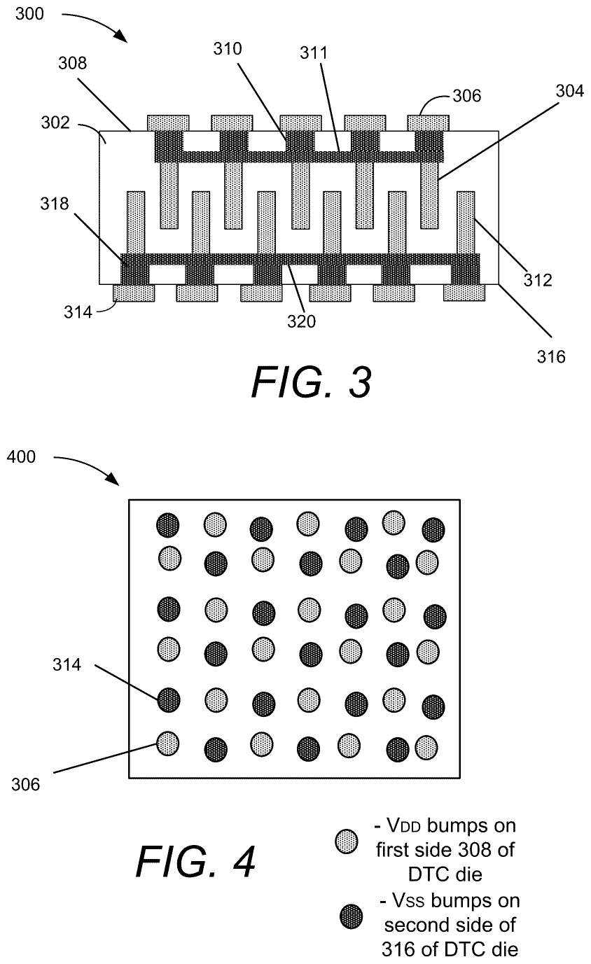

FIG. 3 is a cross-sectional view of a DTC die 300, according to aspects of the disclosure. In this example, the DTC die 300 includes an array of DTCs. In an aspect, The DTC array is formed in a semiconductor substrate 302. The DTC array includes conductive structures 304 that form the first electrodes of the capacitors of the DTC array. Here, conductive structures 304 are connected to voltage bumps 306 at an upper surface 308 of the semiconductor substrate 302 by via structures 310. In this example, the via structures 310 are electrically connected with one another by metallization 311. In FIG. 3, the DTC array also includes conductive structures 312 that form the second electrodes of the capacitors of the array of DTCs. In this example, the conductive structures 312 are connected to voltage bumps 314 at the lower surface 316 of the semiconductor substrate 302 by via structures 318. In an aspect, the via structures 318 may be interconnected with one another by metallization 320.

Certain aspects of the disclosure are directed to reducing the pitch of the voltage bumps on the DTC die 300. In an aspect, the architecture of the DTC die 300 shown in FIG. 3 allows the pitch of the voltage bumps to be reduced by placing the voltage bumps for the electrodes of the array of DTCs at opposite sides of the DTC die 300.

FIG. 4 is a top view 400 of the DTC die 300 showing the voltage bumps on both sides of the DTC die 300 in the same view, according to aspects of the disclosure. In this example, the DTC die 300 includes an array of DTCs (e.g., 20 DTCs). As shown, the voltage bumps for the DTCs of the array are disposed at opposite surfaces 308 and 316 of the DTC die 300. There are two voltage bumps associated with each DTC of the DTC array (e.g., 40 voltage bumps in this example). Each voltage bump 324 is provided for connecting VDD to the first set of electrodes of the capacitors of the DTC array while each voltage bump 314 is provided for connecting the second set of electrodes of the capacitors of the DTC array to Vss.

By reducing the pitch of the voltage bumps, an increased number of bumps may be formed on the same side of the DTC die. A comparison of FIG. 2 and FIG. 4 shows that the number of DTCs in DTC dies of the same size may be doubled (e.g., from 10 DTCs to 20 DTCs). The reduction of the pitch of the voltage bumps, as shown in FIG. 4, may also be leveraged to reduce the die size needed for a given number of DTCs.

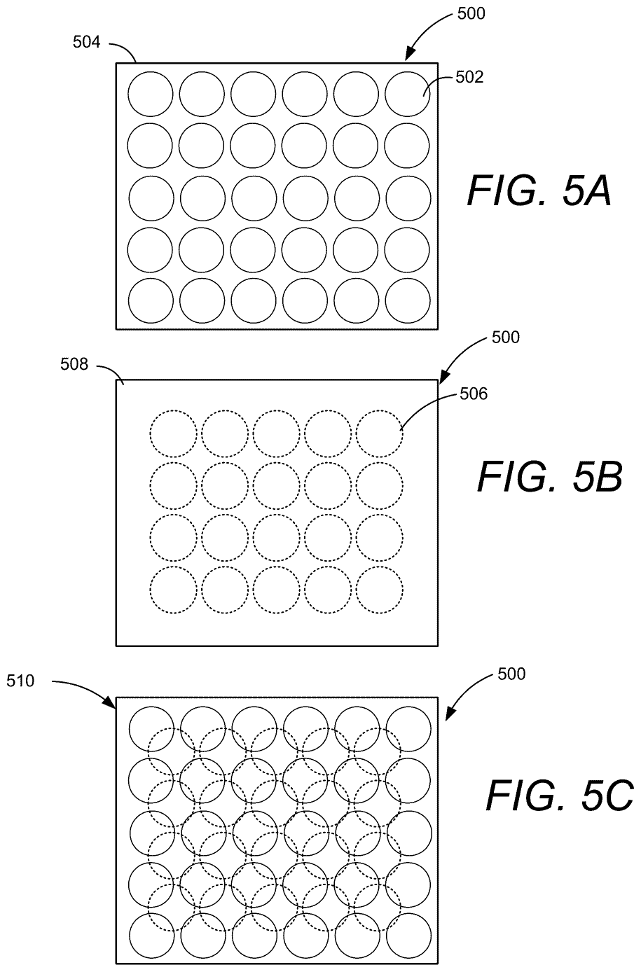

FIG. 5A through FIG. 5C show example layouts of voltage bumps at opposite sides of a DTC die 500, according to aspects of the disclosure. FIG. 5A is a top plan view of the voltage bumps 502 (e.g., V_{DD} bumps) at a first side 504 of the DTC die 500. FIG. 5B is a bottom plan view of the voltage bumps (e.g., V_{SS} bumps) 506 at a second side 508 of the DTC die 500. Based on a comparison of FIG. 5A and FIG. 5B, it is seen that the voltage bumps 502 at the first side 504 of the die are staggered (e.g., not necessarily required to be in vertical alignment) with respect to the voltage bumps 506 at the second side 508. FIG. 5C is a composite view 510 showing the spatial relationship between the voltage bumps 502 at the first side 504 of the DTC die 500 and the voltage bumps 506 at the second side 508 of the DTC die 500.

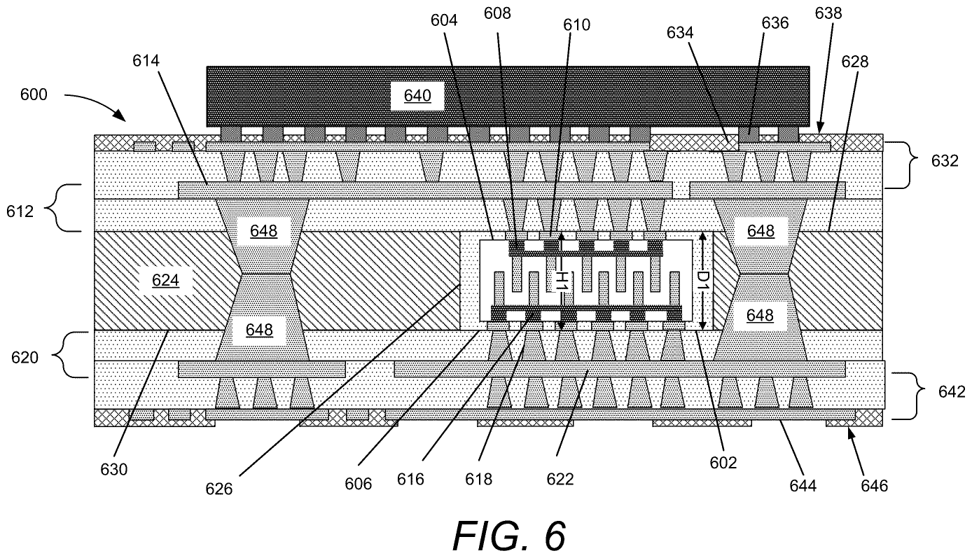

FIG. 6 is a cross-sectional view of an example substrate structure 600, according to aspects of the disclosure. The example substrate structure 600 includes a capacitor die 602 (e.g., a DTC die 300 such as the one shown in FIG. 3) having an array of DTC capacitor structures. The capacitor die 602 includes a first die surface 604 and a second die surface 606 opposite the first die surface 604. A first set of through substrate vias (TSV) 608 extends from a first set of electrodes of the capacitors of the array of capacitors to a first set of contacts 610 (e.g., voltage bumps) at the first die surface 604. A first set of metallization 612 is configured to connect the first set of contacts 610 to a common first supply voltage (e.g., the voltage at metallization line 614). In an aspect, the common first supply voltage is the voltage drain supply V_{DD}.

The capacitor die 602 also includes a second set of TSV 616 extending from a second set of electrodes of the capacitors of the array of capacitors to a second set of contacts 618 (e.g., voltage bumps) at the second die surface 606. A second set of metallization 620 connect the second set of contacts 618 to a common second supply (e.g., the voltage at metallization line 622). In an aspect, the common second supply voltage is the voltage source supply (V_{SS}).

According to aspects of the disclosure, the substrate structure 600 includes a core substrate 624. Here, the core substrate 624 includes a cavity 626 in which the capacitor die 602 is at least partially disposed. In an aspect, the core substrate 624 includes a first core substrate surface 628 and a second core substrate surface 630 opposite the first core substrate surface 628. In an aspect, the cavity 626 extends entirely through the core substrate 624 from the first core substrate surface 628 to the second core substrate surface 630. In FIG. 6, the capacitor die 602 has a height H1 that is substantially the same as the depth D1 of the cavity between the first core substrate surface 628 and the second core layer surface 630.

The substrate structure 600 may include additional features that facilitate the electrical connection of the substrate structure 600 to other electronic components. In FIG. 6, the substrate structure 600 includes a third set of metallization 632 connecting one or more metallization of the first set of metallization 612 to a third set of electrical contacts 634 at a first surface 638 of the substrate structure 600. In this example, the third set of electrical contacts 634 is configured to connect the capacitor structures of the capacitor die 602 to an integrated circuit package 640 (e.g., a system on chip (SoC) die or other integrated circuit suitable for mobile, computer, server, virtual reality, uses).

In FIG. 6, the substrate structure 600 also includes a fourth set of metallization 642 connecting one or more metallization of the second set of metallization 620 to a fourth set of electrical contacts 644 at a second surface 646 of the substrate structure 600 opposite the first surface 638 of the substrate structure 600. In an aspect, the fourth set of electrical contacts is configured for connecting the capacitor structures of the capacitor die 602 to a circuit substrate (e.g., a further substrate, a printed circuit board, etc.)

As also shown in FIG. 6, the substrate structure 600 may include TSV structures 648 through the core substrate 624. The TSV structures 648 provide electrical connections between components located exterior to the core substrate surfaces 628 and 630.

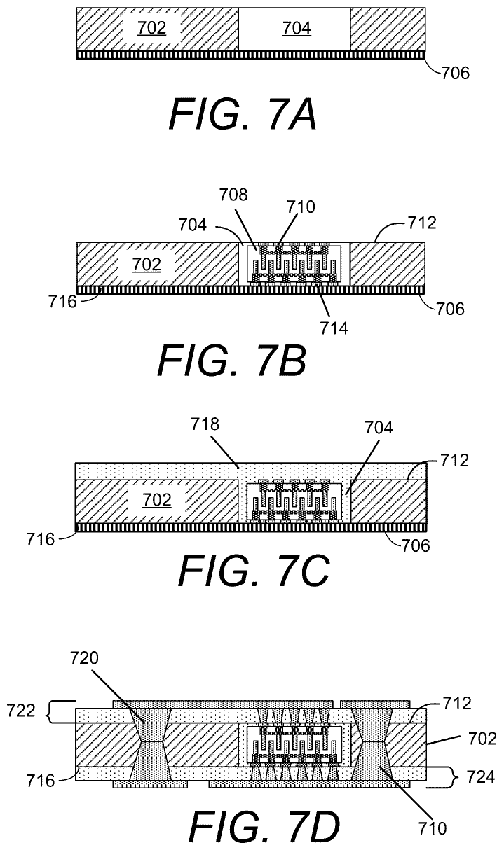

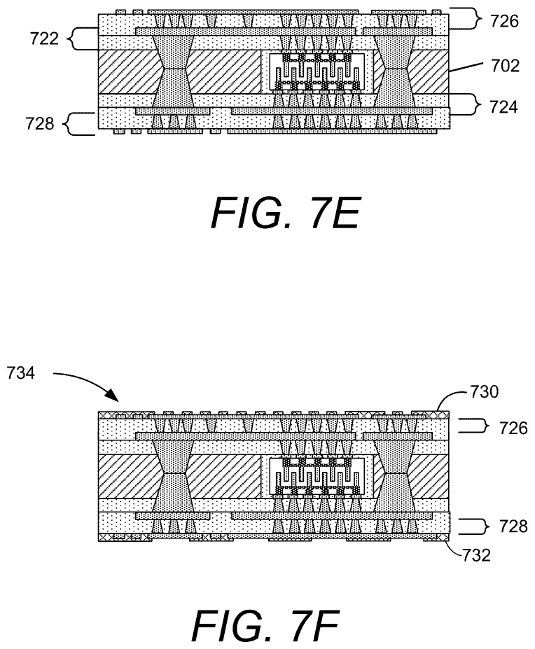

FIG. 7A through FIG. 7F show example operations that may be used to fabricate a substrate structure, according to aspects of the disclosure. At FIG. 7A, a core substrate 702 is provided having a cavity 704. The core substrate 702 is seated upon a tape 706, which covers the bottom of the cavity 704 to facilitate a die embedding operation.

At FIG. 7B, a capacitor die 708 is inserted into the cavity 704 and has its lower face secured by the tape 706. The upper surface of the capacitor die 708 includes voltage bumps 710 that align with the upper surface 712 of the core substrate 702. Similarly, the lower surface of the capacitor die 708 includes voltage bumps 714 that align with a lower surface 716 of the core substrate 702.

At FIG. 7C, a laminate fill operation is used to fill the cavity with a dielectric material 718. In an aspect, the dielectric material 718 may be an Ajinomoto Build-up Film (ABF).

At FIG. 7D, the tape 706 has been removed from the core substrate 702. TSV structures 720 are formed through the core substrate 702. A first set of metallization 722 is formed over the upper surface 712 of the core substrate. Additionally, a second set of metallization 724 are formed over the second core substrate surface 716. In an aspect, the TSV structures 720 electrically connect one or more elements of the first set of metallization 722 with one or more elements of the second set of metallization 724.

At FIG. 7E, further laminate build-up and metallization processes have been performed. As a result of this further processing, a third set of metallization 726 is formed over the first set of metallization 722, and a fourth set of metallization 728 is formed over the third set of metallization 724.

At FIG. 7F, solder resist layers 730 and 732 are formed over the set of third metallization 726 and set of fourth metallization 728, respectively. The resulting substrate structure 734 is ready for subsequent processing, including the mounting of one or more integrated circuits and the formation of connections (e.g., BGA) for mounting the substrate structure 734 to, for example, a printed circuit board or the like.

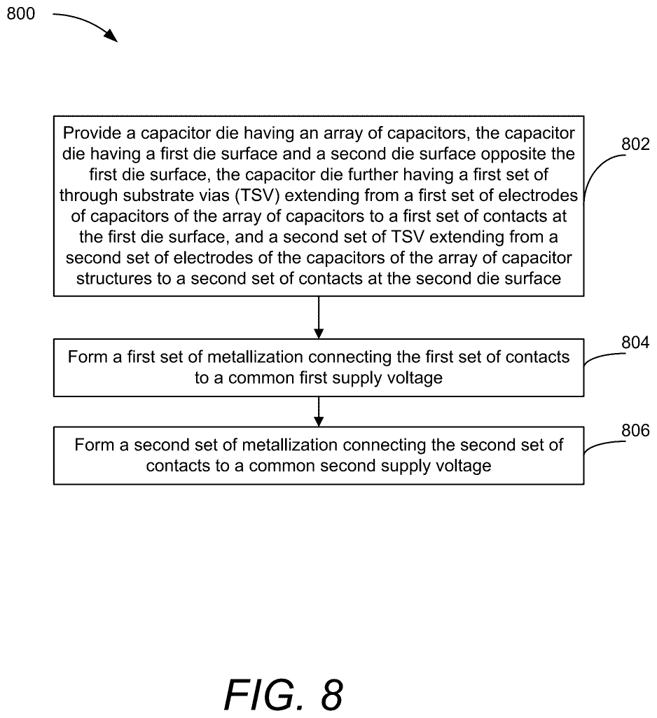

FIG. 8 shows an example method 800 of fabricating a substrate structure, according to aspects of the disclosure. At operation 802, a capacitor die is provided having an array of capacitors, the capacitor die having a first die surface and a second die surface opposite the first die surface, the capacitor die further having a first set of through substrate vias (TSV) extending from a first set of electrodes of capacitors of the array of capacitors to a first set of contacts at the first die surface, and a second set of TSV extending from a second set of electrodes of the capacitors of the array of capacitors to a second set of contacts at the second die surface. At operation 804, a first set of metallization are formed connecting the first set of contacts to a common first supply voltage. At operation 806, a second set of metallization is formed connecting the second set of contacts to a common second supply voltage.

A technical advantage of the method 800 is that it may be used to form a substrate structure having a decrease in the pitch of the voltage bumps on the capacitor die, thereby increasing the voltage bump count for the same size capacitor die. Additionally, the substrate structure allows V_{DD} and V_{SS} connectivity at opposite sides of the substrate structure. Still further, the substrate structure has a reduced equivalent series inductance (ESL) to provide a better effective capacitance value. Still further, the resulting architecture reduces the area occupied by the capacitors, ultimately reducing the cost of the capacitor due to the smaller capacitor.

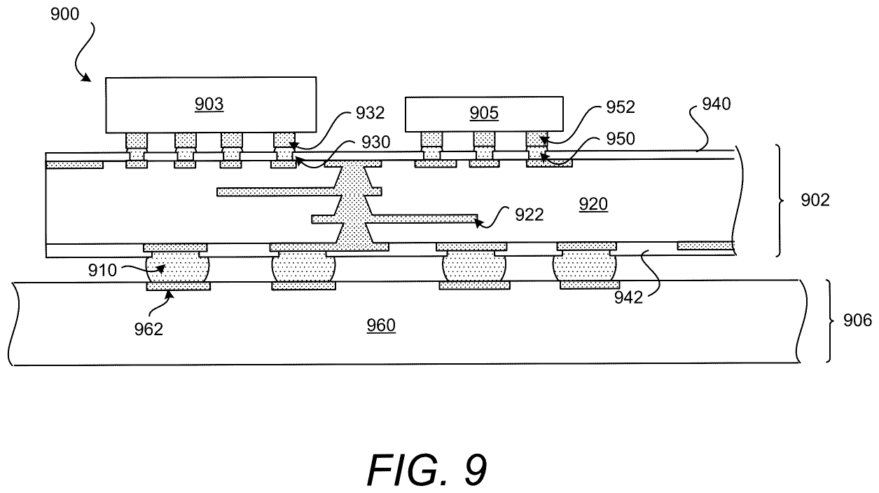

FIG. 9 illustrates a profile view of a package 900 that includes a surface mount substrate 902, an integrated device 903, and an integrated passive device 905, according to aspects of the disclosure. The package 900 may be coupled to a printed circuit board (PCB) 906 through a plurality of solder interconnects 910. The PCB 906 may include at least one board dielectric layer 960 and a plurality of board interconnects 962.

The surface mount substrate 902 includes at least one dielectric layer 920 (e.g., substrate dielectric layer), a plurality of interconnects 922 (e.g., substrate interconnects), a solder resist layer 940 and a solder resist layer 942. The integrated device 903 may be coupled to the surface mount substrate 902 through a plurality of solder interconnects 930. The integrated device 903 may be coupled to the surface mount substrate 902 through a plurality of pillar interconnects 932 and the plurality of solder interconnects 930. The integrated passive device 905 may be coupled to the surface mount substrate 902 through a plurality of solder interconnects 950. The integrated passive device 905 may be coupled to the surface mount substrate 902 through a plurality of pillar interconnects 952 and the plurality of solder interconnects 950.

The package (e.g., 900) may be implemented in a radio frequency (RF) package. The RF package may be a radio frequency front end (RFFE) package. A package (e.g., 900) may be configured to provide Wireless Fidelity (WiFi) communication and/or cellular communication (e.g., 2G, 3G, 4G, 5G). The package (e.g., 900) may be configured to support Global System for Mobile (GSM) Communications, Universal Mobile Telecommunications System (UMTS), and/or Long-Term Evolution (LTE). The package (e.g., 900) may be configured to transmit and receive signals having different frequencies and/or communication protocols.

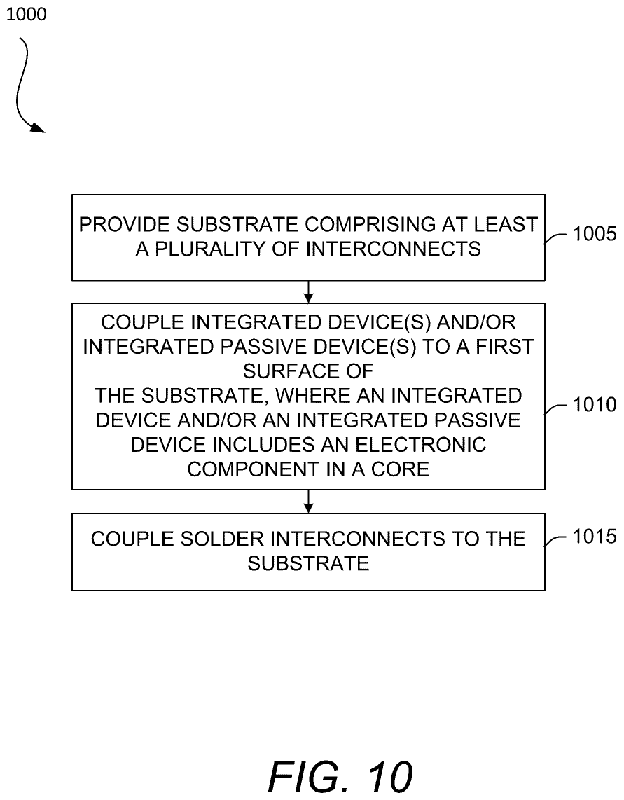

FIG. 10 illustrates an example method 1000 for providing or fabricating a package that includes an integrated device comprising a power splitter, according to aspects of the disclosure. In some implementations, the method 1000 of FIG. 10 may be used to provide or fabricate the package 900 of FIG. 9 described in the disclosure. However, the method 1000 may be used to provide or fabricate any of the packages described in the disclosure.

It should be noted that the method of FIG. 10 may combine one or more processes in order to simplify and/or clarify the method for providing or fabricating a package that includes an integrated device comprising adjacent logic circuits having back-to-back vias, according to aspects of the disclosure. In some implementations, the order of the processes may be changed or modified.

The method provides (at 1005) a substrate (e.g., 902). The substrate 902 may be provided by a supplier or fabricated. The substrate 902 includes at least one dielectric layer 920, and a plurality of interconnects 922. The substrate 902 may include an embedded trace substrate (ETS). In some implementations, the at least one dielectric layer 920 may include prepreg layers.

The method couples (at 1010) at least one integrated device (e.g., 903) to the first surface of the substrate (e.g., 902). For example, the integrated device 903 may be coupled to the substrate 902 through the plurality of pillar interconnects 932 and the plurality of solder interconnects 930. The plurality of pillar interconnects 932 may be optional. The plurality of solder interconnects 930 are coupled to the plurality of interconnects 922. A solder reflow process may be used to couple the integrated device 903 to the plurality of interconnects through the plurality of solder interconnects 930.

The method also couples (at 1010) at least one integrated passive device (e.g., 905) to the first surface of the substrate (e.g., 902). For example, the integrated passive device 905 may be coupled to the substrate 902 through the plurality of pillar interconnects 952 and the plurality of solder interconnects 950. The plurality of pillar interconnects 952 may be optional. The plurality of solder interconnects 950 are coupled to the plurality of interconnects 922. A solder reflow process may be used to couple the integrated passive device 905 to the plurality of interconnects through the plurality of solder interconnects 950.

The method couples (at 1015) a plurality of solder interconnects (e.g., 910) to the second surface of the substrate (e.g., 902). A solder reflow process may be used to couple the plurality of solder interconnects 910 to the substrate.

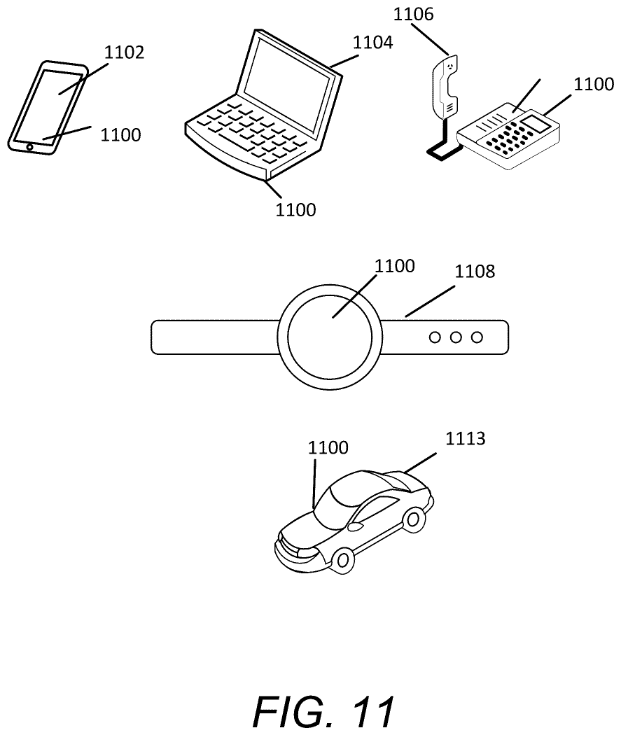

FIG. 11 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 1102, a laptop computer device 1104, a fixed location terminal device 1106, a wearable device 1108, or automotive vehicle 1113 may include a device 1100 as described herein. The device 1100 may be, for example, any of the devices and/or integrated circuit (IC) packages described herein. The devices 1102, 1104, 1106 and 1108 and the vehicle 1113 illustrated in FIG. 11 are merely exemplary. Other electronic devices may also feature the device 1100 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

Implementation examples are described in the following numbered aspects:
Aspect 1. An electronic device, comprising: a substrate structure comprising a capacitor die having an array of capacitors, the capacitor die having a first die surface and a second die surface opposite the first die surface; a first set of through substrate vias (TSV) extending from a first set of electrodes of capacitors of the array of capacitors to a first set of contacts at the first die surface; a first set of metallization connecting the first set of contacts to a common first supply voltage; a second set of TSV extending from a second set of electrodes of the capacitors of the array of capacitors to a second set of contacts at the second die surface; and a second set of metallization connecting the second set of contacts to a common second supply voltage.
Aspect 2. The electronic device of aspect 1, wherein: the array of capacitors comprises an array of deep trench capacitors (DTC).
Aspect 3. The electronic device of any of aspects 1 to 2, wherein: the common first supply voltage is a voltage drain supply voltage (Vdd); and the common second supply voltage is a voltage source supply voltage (Vss).
Aspect 4. The electronic device of any of aspects 1 to 3, further comprising: a core substrate having a cavity, wherein the capacitor die is at least partially disposed in the cavity.
Aspect 5. The electronic device of aspect 4, wherein: the core substrate includes a first core substrate surface and a second core substrate surface opposite the first core substrate surface; and the cavity extends entirely through the core substrate from the first core substrate surface to the second core substrate surface.
Aspect 6. The electronic device of aspect 5, wherein: the capacitor die has a height that is equal to a depth of the cavity between the first core substrate surface and the second core substrate surface.
Aspect 7. The electronic device of any of aspects 1 to 6, further comprising: a third set of metallization connecting one or more metallization of the first set of metallization to a third set of electrical contacts at a first surface of the substrate structure, wherein the third set of electrical contacts are configured for connecting the capacitor structures of the array of capacitors to an integrated circuit package; and a fourth set of metallization connecting one or more metallization of the second set of metallization to a fourth set of electrical contacts at a second surface of the substrate structure opposite the first surface of the substrate structure, wherein the fourth set of electrical contacts are configured for connecting the capacitor structures of the array of capacitors to a circuit substrate.
Aspect 8. The electronic device of any of aspects 1 to 7, wherein the electronic device comprises at least one of: a music player; a video player; an entertainment unit; a navigation device; a communications device; a mobile device; a mobile phone; a smartphone; a personal digital assistant; a fixed location terminal; a tablet computer, a computer; a wearable device; a laptop computer; a server; an internet of things (IoT) device; or a device in an automotive vehicle.
Aspect 9. A substrate structure comprising: a capacitor die having an array of capacitors, the capacitor die having a first die surface and a second die surface opposite the first die surface; a first set of through substrate vias (TSV) extending from a first set of electrodes of capacitors of the array of capacitors to a first set of contacts at the first die surface; a first set of metallization connecting the first set of contacts to a common first supply voltage; a second set of TSV extending from a second set of electrodes of the capacitors of the array of capacitors to a second set of contacts at the second die surface; and a second set of metallization connecting the second set of contacts to a common second supply voltage.
Aspect 10. The substrate structure of aspect 9, wherein: the array of capacitors comprises an array of deep trench capacitors (DTC).
Aspect 11. The substrate structure of any of aspects 9 to 10, wherein: the common first supply voltage is a voltage drain supply voltage (Vdd); and the common second supply voltage is a voltage source supply voltage (Vss).
Aspect 12. The substrate structure of any of aspects 9 to 11, further comprising: a core substrate having a cavity, wherein the capacitor die is at least partially disposed in the cavity.
Aspect 13. The substrate structure of aspect 12, wherein: the core substrate includes a first core substrate surface and a second core substrate surface opposite the first core substrate surface; and the cavity extends entirely through the core substrate from the first core substrate surface to the second core substrate surface.
Aspect 14. The substrate structure of aspect 13, wherein: the capacitor die has a height that is equal to a depth of the cavity between the first core substrate surface and the second core substrate surface.
Aspect 15. The substrate structure of any of aspects 9 to 14, further comprising: a third set of metallization connecting one or more metallization of the first set of metallization to a third set of electrical contacts at a first surface of the substrate structure, wherein the third set of electrical contacts are configured for connecting the capacitor structures of the array of capacitors to an integrated circuit package; and a fourth set of metallization connecting one or more metallization of the second set of metallization to a fourth set of electrical contacts at a second surface of the substrate structure opposite the first surface of the substrate structure, wherein the fourth set of electrical contacts are configured for connecting the capacitor structures of the array of capacitors to a circuit substrate.
Aspect 16. A method of fabricating a substrate structure comprising: providing a capacitor die having an array of capacitors, the capacitor die having a first die surface and a second die surface opposite the first die surface, the capacitor die further having a first set of through substrate vias (TSV) extending from a first set of electrodes of capacitors of the array of capacitors to a first set of contacts at the first die surface, and a second set of TSV extending from a second set of electrodes of the capacitors of the array of capacitors to a second set of contacts at the second die surface; forming a first set of metallization connecting the first set of contacts to a common first supply voltage; and and forming a second set of metallization connecting the second set of contacts to a common second supply voltage.
Aspect 17. The method of aspect 16, wherein: the array of capacitors comprises an array of deep trench capacitors (DTC).
Aspect 18. The method of any of aspects 16 to 17, further comprising: forming a core substrate having a cavity, wherein the capacitor die is at least partially disposed in the cavity.
Aspect 19. The method of aspect 18, wherein: the core substrate includes a first core substrate surface and a second core substrate surface opposite the first core substrate surface; and the cavity extends entirely through the core substrate from the first core substrate surface to the second core substrate surface.
Aspect 20. The method of any of aspects 16 to 19, further comprising: forming a third set of metallization connecting one or more metallization of the first set of metallization to a third set of electrical contacts at a first surface of the substrate structure, wherein the third set of electrical contacts are configured for connecting the capacitor structures of the array of capacitors to an integrated circuit package; and forming a fourth set of metallization connecting one or more metallization of the second set of metallization to a fourth set of electrical contacts at a second surface of the substrate structure opposite the first surface of the substrate structure, wherein the fourth set of electrical contacts are configured for connecting the capacitor structures of the array of capacitors to a circuit substrate.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

It is noted that the figures in the disclosure may represent actual representations and/or conceptual representations of various parts, components, objects, devices, packages, integrated devices, integrated circuits, and/or transistors. In some instances, the figures may not be to scale. In some instances, for the purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metallization layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the detailed description above, it can be seen that different features are grouped together in examples. This manner of disclosure should not be understood as an intention that the example aspects have more features than are explicitly mentioned in each aspect. Rather, the various aspects of the disclosure may include fewer than all features of an individual example aspect disclosed. Therefore, the following aspects should hereby be deemed to be incorporated in the description, wherein each aspect by itself can stand as a separate example. Although each dependent aspect can refer in the aspects to a specific combination with one of the other aspects, the aspect(s) of that dependent aspect are not limited to the specific combination. It will be appreciated that other example aspects can also include a combination of the dependent aspect(s) with the subject matter of any other dependent aspect or independent aspect or a combination of any feature with other dependent and independent aspects. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of an aspect can be included in any other independent aspect, even if the aspect is not directly dependent on the independent aspect.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An electronic device, comprising:
a substrate structure comprising
a capacitor die having an array of capacitors, the capacitor die having a first die surface and a second die surface opposite the first die surface;
a first set of through substrate vias (TSV) extending from a first set of electrodes of capacitors of the array of capacitors to a first set of contacts at the first die surface;
a first set of metallization connecting the first set of contacts to a common first supply voltage;
a second set of TSV extending from a second set of electrodes of the capacitors of the array of capacitors to a second set of contacts at the second die surface; and
a second set of metallization connecting the second set of contacts to a common second supply voltage.

2. The electronic device of claim 1, wherein:
the array of capacitors comprises an array of deep trench capacitors (DTC).

3. The electronic device of claim 1, wherein:
the common first supply voltage is a voltage drain supply voltage (Vdd); and
the common second supply voltage is a voltage source supply voltage (Vss).

4. The electronic device of claim 1, further comprising:
a core substrate having a cavity, wherein the capacitor die is at least partially disposed in the cavity.

5. The electronic device of claim 4, wherein:
the core substrate includes a first core substrate surface and a second core substrate surface opposite the first core substrate surface; and
the cavity extends entirely through the core substrate from the first core substrate surface to the second core substrate surface.

6. The electronic device of claim 5, wherein:
the capacitor die has a height that is equal to a depth of the cavity between the first core substrate surface and the second core substrate surface.

7. The electronic device of claim 1, further comprising:
a third set of metallization connecting one or more metallization of the first set of metallization to a third set of electrical contacts at a first surface of the substrate structure, wherein the third set of electrical contacts are configured for connecting the capacitor structures of the array of capacitors to an integrated circuit package; and
a fourth set of metallization connecting one or more metallization of the second set of metallization to a fourth set of electrical contacts at a second surface of the substrate structure opposite the first surface of the substrate structure, wherein the fourth set of electrical contacts are configured for connecting the capacitor structures of the array of capacitors to a circuit substrate.

8. The electronic device of claim 1, wherein the electronic device comprises at least one of:
a music player;
a video player;
an entertainment unit;
a navigation device;
a communications device;
a mobile device;
a mobile phone;
a smartphone;
a personal digital assistant;
a fixed location terminal;
a tablet computer, a computer;
a wearable device;
a laptop computer;
a server;
an internet of things (IoT) device; or
a device in an automotive vehicle.

9. A substrate structure comprising:
a capacitor die having an array of capacitors, the capacitor die having a first die surface and a second die surface opposite the first die surface;
a first set of through substrate vias (TSV) extending from a first set of electrodes of capacitors of the array of capacitors to a first set of contacts at the first die surface;
a first set of metallization connecting the first set of contacts to a common first supply voltage;
a second set of TSV extending from a second set of electrodes of the capacitors of the array of capacitors to a second set of contacts at the second die surface; and
a second set of metallization connecting the second set of contacts to a common second supply voltage.

10. The substrate structure of claim 9, wherein:
the array of capacitors comprises an array of deep trench capacitors (DTC).

11. The substrate structure of claim 9, wherein:
the common first supply voltage is a voltage drain supply voltage (Vdd); and
the common second supply voltage is a voltage source supply voltage (Vss).

12. The substrate structure of claim 9, further comprising:
a core substrate having a cavity, wherein the capacitor die is at least partially disposed in the cavity.

13. The substrate structure of claim 12, wherein:
the core substrate includes a first core substrate surface and a second core substrate surface opposite the first core substrate surface; and
the cavity extends entirely through the core substrate from the first core substrate surface to the second core substrate surface.

14. The substrate structure of claim 13, wherein:
the capacitor die has a height that is equal to a depth of the cavity between the first core substrate surface and the second core substrate surface.

15. The substrate structure of claim 9, further comprising:
a third set of metallization connecting one or more metallization of the first set of metallization to a third set of electrical contacts at a first surface of the substrate structure, wherein the third set of electrical contacts are configured for connecting the capacitor structures of the array of capacitors to an integrated circuit package; and
a fourth set of metallization connecting one or more metallization of the second set of metallization to a fourth set of electrical contacts at a second surface of the substrate structure opposite the first surface of the substrate structure, wherein the fourth set of electrical contacts are configured for connecting the capacitor structures of the array of capacitors to a circuit substrate.

16. A method of fabricating a substrate structure comprising:
providing a capacitor die having an array of capacitors, the capacitor die having a first die surface and a second die surface opposite the first die surface, the capacitor die further having a first set of through substrate vias (TSV) extending from a first set of electrodes of capacitors of the array of capacitors to a first set of contacts at the first die surface, and a second set of TSV extending from a second set of electrodes of the capacitors of the array of capacitors to a second set of contacts at the second die surface;
forming a first set of metallization connecting the first set of contacts to a common first supply voltage; and and
forming a second set of metallization connecting the second set of contacts to a common second supply voltage.

17. The method of claim 16, wherein:
the array of capacitors comprises an array of deep trench capacitors (DTC).

18. The method of claim 16, further comprising:
forming a core substrate having a cavity, wherein the capacitor die is at least partially disposed in the cavity.

19. The method of claim 18, wherein:
the core substrate includes a first core substrate surface and a second core substrate surface opposite the first core substrate surface; and
the cavity extends entirely through the core substrate from the first core substrate surface to the second core substrate surface.

20. The method of claim 16, further comprising:
forming a third set of metallization connecting one or more metallization of the first set of metallization to a third set of electrical contacts at a first surface of the substrate structure, wherein the third set of electrical contacts are configured for connecting the capacitor structures of the array of capacitors to an integrated circuit package; and
forming a fourth set of metallization connecting one or more metallization of the second set of metallization to a fourth set of electrical contacts at a second surface of the substrate structure opposite the first surface of the substrate structure, wherein the fourth set of electrical contacts are configured for connecting the capacitor structures of the array of capacitors to a circuit substrate.
